(19) United States
(12) Patent Application Publication
(10) Pub. No.: US 2026/0005142 A1
(43) Pub. Date: Jan. 1, 2026

(54) INNER SPACER AS ETCH STOP LAYER FOR BACKSIDE POWER RAIL

(71) Applicant: INTERNATIONAL BUSINESS MACHINES CORPORATION, ARMONK, NY (US)

(72) Inventors: Ruilong Xie, Niskayuna, NY (US); Tao Li, Slingerlands, NY (US); HUIMEI ZHOU, Albany, NY (US); Reinaldo Vega, Mahopac, NY (US); Xiaoming Yang, Clifton Park, NY (US)

(21) Appl. No.: 18/756,039

(22) Filed: Jun. 27, 2024

(51) Int. Cl. H01L 23/528; H01L 21/768; H01L 23/522; H01L 29/06; H01L 29/66; H01L 29/775; H01L 29/786

(52) U.S. Cl. CPC H01L 23/5286; H01L 21/76832; H01L 21/76877; H01L 23/5226; H10D 62/116; H10D 30/014; H10D 30/43; H10D 30/6757; H10D 62/121

(57) ABSTRACT

Embodiments disclosed herein include a semiconductor structure. The semiconductor structure may include a deep via connecting a first source/drain (S/D) to a backside power rail (RB) below the first S/D, a dielectric etch stop inner spacer below the first S/D, and an RB sidewall surrounding the RB comprising an edge laterally overlapping the dielectric etch stop inner spacer.

### BACKGROUND

The present invention relates generally to the field of semiconductor device manufacturing, and more particularly to alignment of backside power rails.

Backside power rails, also known as a Backside Power Delivery Network (BSPDN), is an approach in semiconductor technology that involves delivering power on the backside of a chip. This approach separates power and signal wiring, shifting power lines to the back of the wafer. The concept of backside power delivery tackles problems such as increased via resistances in the back-end-of-line (BEOL) due to shrinking signal paths, and the separation of the power ultimately improves the performance of transistors and lowers power consumption. The power supply may even be relocated from conventional BEOL on the front of the wafer to the backside. This architecture can potentially reduce the IR drop between the power rail and the active device.

### SUMMARY

Aspects of an embodiment of the present invention include a semiconductor structure. The semiconductor structure may include a deep via connecting a first source/drain (S/D) to a backside power rail (RB) below the first S/D, a dielectric etch stop inner spacer below the first S/D, and an RB sidewall surrounding the RB comprising an edge laterally overlapping the dielectric etch stop inner spacer.

Aspects of an embodiment of the present invention encompass a method of fabricating a semiconductor structure. The method may include etching an indentation in a silicon/germanium (SiGe) etch stop layer below a first source/drain, filling the indentation with a dielectric etch stop inner spacer, forming a deep via, and forming a backside power rail (RB) trench to expose the deep via. The dielectric etch stop inner spacer may stop the etch process that forms the RB trench.

Aspects of an embodiment of the present invention include a semiconductor structure. The semiconductor structure may include a dielectric etch stop inner spacer below a first source/drain with a spacer thickness, a silicon/germanium (SiGe) layer adjacent to the dielectric etch stop inner spacer with a thickness that is the same as the spacer thickness, and an RB sidewall having an edge laterally overlapping the dielectric etch stop inner spacer.

### BRIEF DESCRIPTION OF THE DRAWINGS

FIG. 1 depicts a schematic top view of a semiconductor structure at a stage of fabrication, in accordance with one embodiment of the present invention.

FIG. 2 depicts a cross-sectional side view of the semiconductor structure of FIG. 1 at a fabrication stage of the processing method, in accordance with one embodiment of the present invention.

FIG. 3 depicts a cross-sectional side view of the semiconductor structure of FIG. 1 at a fabrication stage of the processing method, in accordance with one embodiment of the present invention.

FIG. 4 depicts a cross-sectional side view of the semiconductor structure of FIG. 1 at a fabrication stage of the processing method, in accordance with one embodiment of the present invention.

FIG. 5 depicts a cross-sectional side view of the semiconductor structure of FIG. 1 at a fabrication stage of the processing method, in accordance with one embodiment of the present invention.

FIG. 6 depicts a cross-sectional side view of the semiconductor structure of FIG. 1 at a fabrication stage of the processing method, in accordance with one embodiment of the present invention.

FIG. 7 depicts a cross-sectional side view of the semiconductor structure of FIG. 1 at a fabrication stage of the processing method, in accordance with one embodiment of the present invention.

FIG. 8 depicts a cross-sectional side view of the semiconductor structure of FIG. 1 at a fabrication stage of the processing method, in accordance with one embodiment of the present invention.

FIG. 9 depicts a cross-sectional side view of the semiconductor structure of FIG. 1 at a fabrication stage of the processing method, in accordance with one embodiment of the present invention.

FIG. 10 depicts a cross-sectional side view of the semiconductor structure of FIG. 1 at a fabrication stage of the processing method, in accordance with one embodiment of the present invention.

FIG. 11 depicts a cross-sectional side view of the semiconductor structure of FIG. 1 at a fabrication stage of the processing method, in accordance with one embodiment of the present invention.

FIG. 12 depicts a cross-sectional side view of the semiconductor structure of FIG. 1 at a fabrication stage of the processing method, in accordance with one embodiment of the present invention.

FIG. 13 depicts a cross-sectional side view of the semiconductor structure of FIG. 1 at a fabrication stage of the processing method, in accordance with one embodiment of the present invention.

FIG. 14 depicts a cross-sectional side view of the semiconductor structure of FIG. 1 at a fabrication stage of the processing method, in accordance with one embodiment of the present invention.

FIG. 15 depicts a cross-sectional side view of the semiconductor structure of FIG. 1 at a fabrication stage of the processing method, in accordance with one embodiment of the present invention.

FIG. 16 depicts a cross-sectional side view of the semiconductor structure of FIG. 1 at a fabrication stage of the processing method, in accordance with one embodiment of the present invention.

FIG. 17 depicts a cross-sectional side view of a semiconductor structure at a fabrication stage of the processing method, in accordance with one embodiment of the present invention.

FIG. 18 depicts a cross-sectional side view of the semiconductor structure of FIG. 17 at a fabrication stage of the processing method, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Improvements in the design of integrated circuits (IC) have enabled feature sizes for transistors in a device layer to enter into deep submicron and nanometer regime. Embodiments herein recognize benefits from separating the power delivery components from the signal wires. A backside power delivery network (BSPDN), for example, can greatly improve the routability for field-effect transistors (FETs). Improving routability means the design of the IC provides easier connection between source/drains (S/Ds), gates, etc., and the other components of the IC. Embodiments herein also recognize that the decrease in feature size can mean a greater potential for defect even with very slight misalignment in a lithographic mask. This is particularly important in the formation of a backside power rail contacting a backside via that conveys a signal from a frontside source/drain. Processes used to expose the backside via can potentially damage the backside via since controlling the depth in such small spaces is difficult.

Embodiments described herein, therefore, are fabricated with a dielectric etch stop inner spacer. The dielectric etch stop inner spacer may be below the source/drain to control the depth of the backside power rail trench, and ensure proper exposure of the backside via before the backside power rail is metalized. Advantages of having a dielectric etch stop inner spacer, therefore, include backside power rails that are sufficiently connected (electrically) to the backside via with an increased protection against shorts within the semiconductor structure.

Embodiments of the present invention and an example fabrication process will now be described in detail with reference to the Figures.

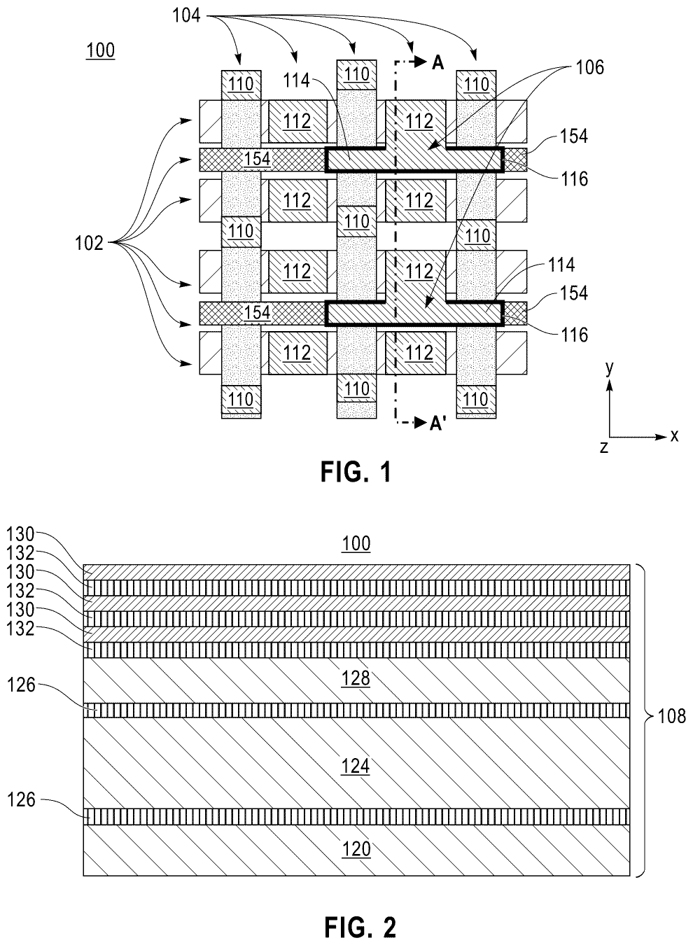

FIG. 1 depicts a schematic top view of a semiconductor structure 100 at a stage of fabrication, in accordance with one embodiment of the present invention. The semiconductor structure 100 is organized as rows 102 and columns 104 of field-effect transistor (FET) devices 106 fabricated in a device layer (i.e., front-end-of-line (FEOL) 108 in subsequent figures) of the semiconductor structure 100. The columns 104 include gates operated through gate contacts 110 that control channels between source/drains (S/Ds) operated through S/D contacts 112 of the FET devices 106. The semiconductor structure 100 electrically connects the S/Ds and gates to a back-end-of-line (BEOL) interconnect network on a front side of the semiconductor structure 100 and/or to a backside power delivery network (BSPDN) on a backside of the semiconductor structure 100.

The semiconductor structure 100 also includes backside vias 114 connected to the frontside S/D contacts 112. The backside vias 114 may be fabricated (as shown) with a longer dimension along the rows 102 (i.e., x-direction) to compensate for the shorter dimension between the rows (i.e., y-direction). In certain embodiments the backside vias 114 may also be fabricated with an x-direction dimension that is the same as the x-direction dimension of the frontside S/D contacts 112. The backside vias 114 are further insulated from neighboring contacts 112, 110 by backside via liners 116, and contact the BSPDN below the S/Ds, as explained in detail below. In particular, the formation of backside power rails (RB) that securely contact the backside vias 114 reduces the potential for shorting (e.g., to the gate, source/drains, or other components of the FET devices 106) by precisely and accurately etching an RB trench. The semiconductor structure 100 may also include a substrate contact 112 configured to supply a voltage potential to a substrate below the devices 106. This voltage potential in the lower substrate may enable single direction signal flow between pairs of S/Ds. This means that the pairs of S/Ds may act like passive devices (e.g., diodes), and be programmed to perform as such.

FIG. 2 depicts a cross-sectional side view of the semiconductor structure 100 of FIG. 1, with like reference numerals referring to like features at a fabrication stage of the processing method, in accordance with one embodiment of the present invention. FIG. 2 depicts the view along line A-A′ in FIG. 1. The semiconductor structure 100 includes the FEOL 108 before the formation of the FET devices 106. The FEOL 108 starts fabrication as a base substrate 120 on which layers are deposited and selectively removed using lithographically patterned masks followed by etch processes. In FIG. 2 the blanket layers deposited on the base substrate 120 have not been patterned yet, and include a first etch stop layer 122, a lower substrate 124, a second etch stop layer 126, an upper substrate 128, nanosheet channels 130, and dummy layers 132. The nanosheet channels 130 will eventually form the gates of the FET devices 106, but other gate structures and channel structures may function with the dielectric etch stop inner spacer and backside power rail described herein.

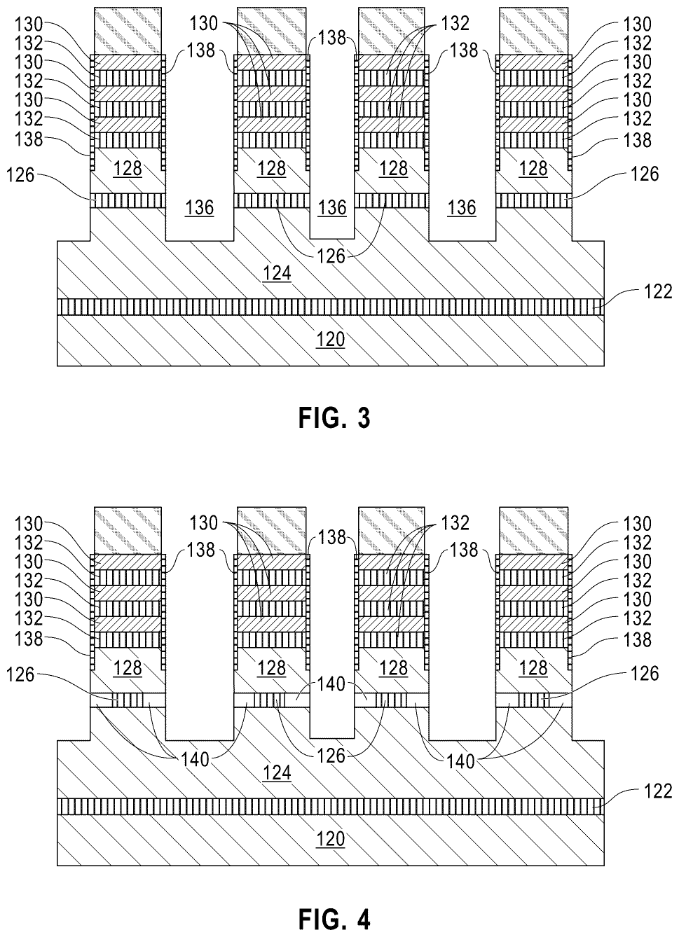

FIG. 3 depicts a cross-sectional side view of the semiconductor structure 100 of FIG. 1, with like reference numerals referring to like features at a fabrication stage of the processing method, in accordance with one embodiment of the present invention. FIG. 3 depicts the view along line A-A′ in FIG. 1. The fabrication process includes the use of a hard mask 134 that enables an etch process (e.g., reactive ion etch (RIE)) to form shallow trench isolation (STI) trenches 132 along the rows 102 of the semiconductor structure 100. The STI trenches 136 may be formed in multiple etch stages, with depositions or other fabrication steps between. For example, a first etch process may etch the STI trenches 136 to a first depth followed by a deposition and breakthrough of a sidewall liner 138. Breakthrough of the sidewall liner 138 means that after a blanket layer of the sidewall liner 138 is applied over the entire top surface of the semiconductor structure 100, a directional etch process etches the horizontal portions of the sidewall liner 138, which leaves the vertical portions shown in FIG. 3.

An additional etch process may then be used to extend the STI trenches 136 deeper into the semiconductor structure 100. That is, the STI trenches 136 may extend through the upper substrate 128, the second etch stop layer 126, and partially into the lower substrate 124. The lower substrate 124 is not etched fully, however, and a portion of the lower substrate 124 is kept such some silicon remains below the STI trenches 136. The exposure of the second etch stop layer 126 (at the edges within the STI trenches) is especially pertinent to the next stage illustrated in FIG. 4.

FIG. 4 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the formation of a dielectric etch stop inner spacer 140 that provides a non-conductive barrier during a subsequent etch process from the backside to form the RB trench. The dielectric etch stop inner spacer 140 may be formed by recessing the second etch stop layer 126 and replacing the recessed portion with a dielectric material. To recess the second etch stop layer 126, a process that selectively etches SiGe may be used. This selective etch process does not affect the silicon of the upper substrate 128 and lower substrate 124, or the dielectric material of the sidewall liner 138. A specific timing of the selective etch process is calculated to leave a portion of the second etch stop layer 126 which enables the upper substrate 128 and the lower substrate 124 to electrically communicate, conveying signals and maintaining a potential between the two.

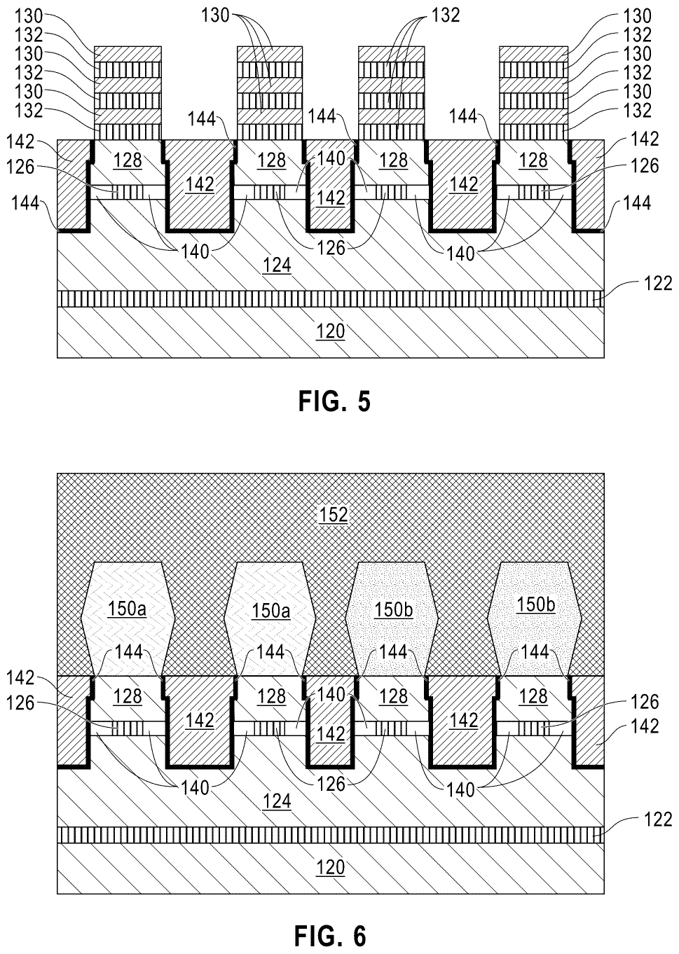

FIG. 5 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the addition of a shallow trench isolation (STI) 138 to provide isolation of the active regions of the FET devices 106. The STI 142 includes dielectric materials such as silicon oxide and may include a STI liner 144 lining the STI 142. The STI 142 may be applied as a blanket deposition followed by recession of the STI dielectric material to a level below the nanosheet channels 130 and the dummy layer 132.

FIG. 6 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the formation of source/drains (S/Ds) 150a, b. The S/Ds 150a, b are fabricated using epitaxial growth, and include: PFET S/Ds 150a formed, for example, from silicon germanium (SiGe) doped with boron; and NFET S/Ds 150b formed, for example, from silicon doped with phosphorus. To create space for the S/Ds 150a, b, the nanosheet channels 130 and the dummy layers 132 may be etched along columns. The nanosheet channels 130 and dummy layers 132 remain unetched in columns located between the columns of S/Ds 150a, b, forming the columns attached to the gate contacts 110 illustrated in FIG. 1. After the formation of the S/Ds 150a, b, a protective layer of interlayer dielectric (ILD) 152 is laid over the semiconductor structure 100. The ILD 152 may be smoothed flat with a chemical-mechanical polishing (CMP) step.

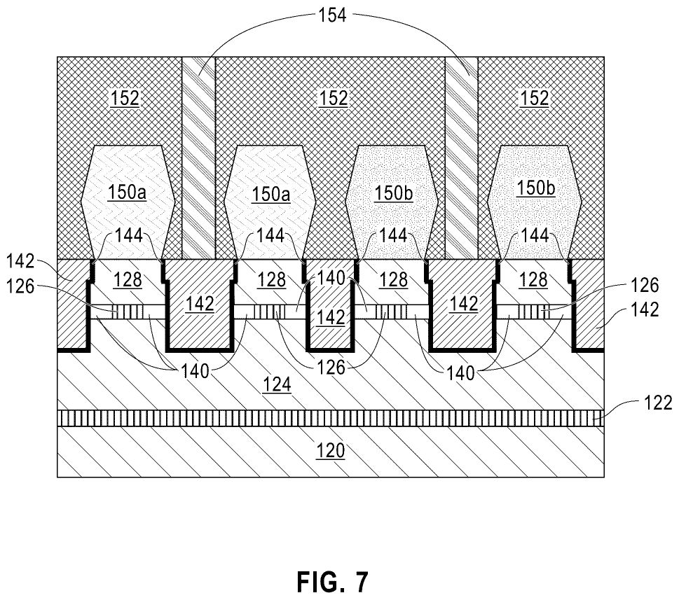

FIG. 7 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the formation of gate cut region at cell boundaries with dielectric fill 154 that divide the S/Ds 150 of the same type. That is, a first dielectric fill 154 divides the PFET S/Ds 150a and a second dielectric fill 154 divides the NFET S/Ds 150b. The dielectric fill 154 may be formed using a hard mask patterned with lithography, followed by the lines and filling the lines with a dielectric fill material that is electrically insulative.

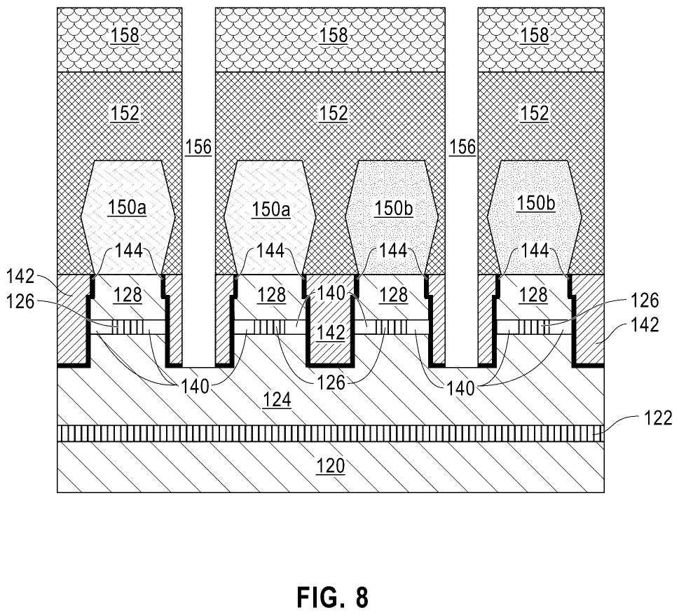

FIG. 8 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the formation of deep via holes 156, expanding and replacing certain areas of the dielectric fill 154. The deep via holes 156 may also be formed through the use of a hard mask 158, which is shown in FIG. 8 (but not shown for the step of forming the dielectric fill 154 in FIG. 7).

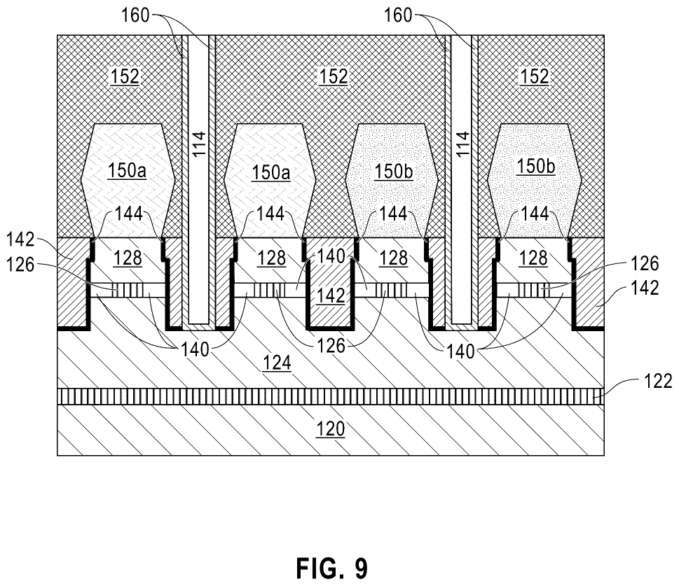

FIG. 9 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include formation of the backside vias 114 lined by deep via liners 160. The difference in length between the backside vias 114 (i.e., deep via holes 156) and the dielectric fill 154 is not particularly apparent in FIG. 8, but is shown in FIG. 1. Specifically, FIG. 1 shows that the deep via holes 156 are not etched in trenches along the length of a row 102, but are rather focused on the areas between specific S/Ds 150a, b.

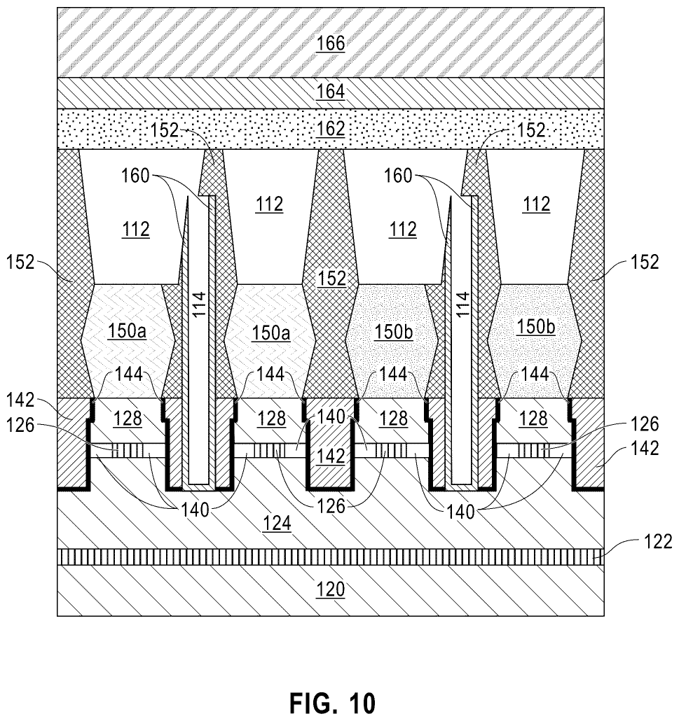

FIG. 10 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include a back-end-of-line (BEOL) 162 connecting the S/D contacts 112 to the external electronics. The BEOL 162 is not drawn to scale, and may include several metal layers of crisscrossing interconnects to connect the gate contacts 110 and the S/D contacts 112. The metal layers of interconnects may increase in size (i.e., height and width of interconnect lines) with each subsequently formed layer. The formation of the BEOL 162 may be followed by the formation of a bonding oxide 164 and a carrier wafer 166 bonded to the semiconductor structure 100 to facilitate flipping and fabrication processes on the backside of the semiconductor structure 100.

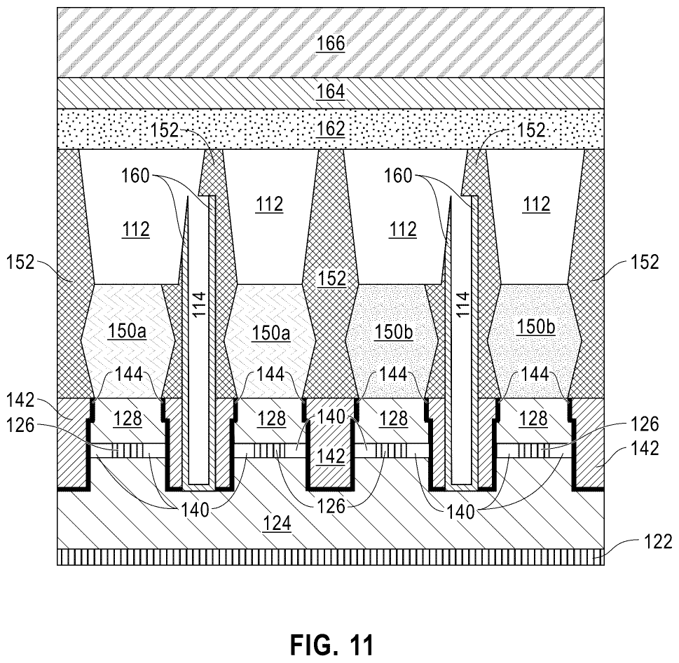

FIG. 11 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include removal of the base substrate 120 below the first etch stop layer 122. The carrier wafer 166 supports the semiconductor structure 100 securely to prevent physical stresses from causing defects during the removal of the base substrate 120. The first etch stop layer 122 is monitored such that when the etch process to remove the base substrate 120 contacts the first etch stop layer 122, the etch process is triggered to stop. This triggering enables a rough/quick method(s) to remove the thicker base substrate 120 without endangering the delicate components within the FEOL 108.

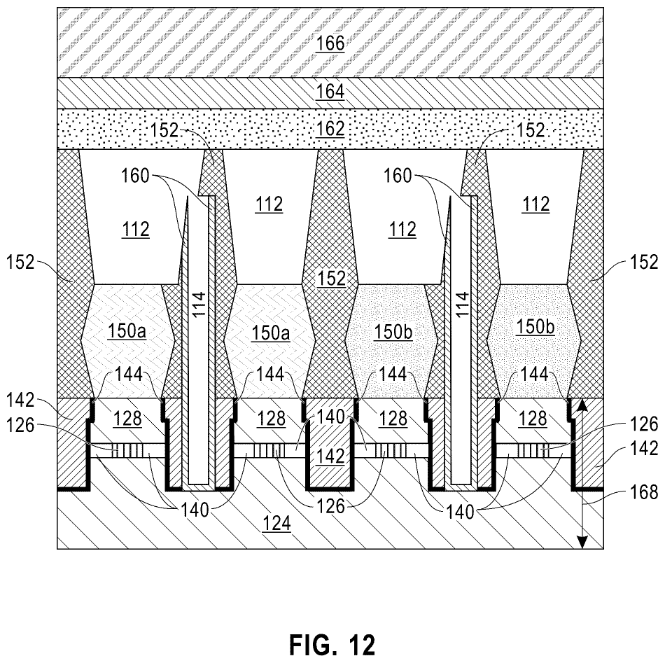

FIG. 12 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include removing the first etch stop layer 122 and thinning the lower substrate 124 from the backside. The thinning process may be more controlled than the process to remove the base substrate 120, which enables a more precise adjustment of a backside thickness 168. In certain embodiments, a desirable backside thickness 168 may be 150 nm. The control of the backside thickness 168 enables consistent backside access to the backside vias 114 for the later steps detailed below.

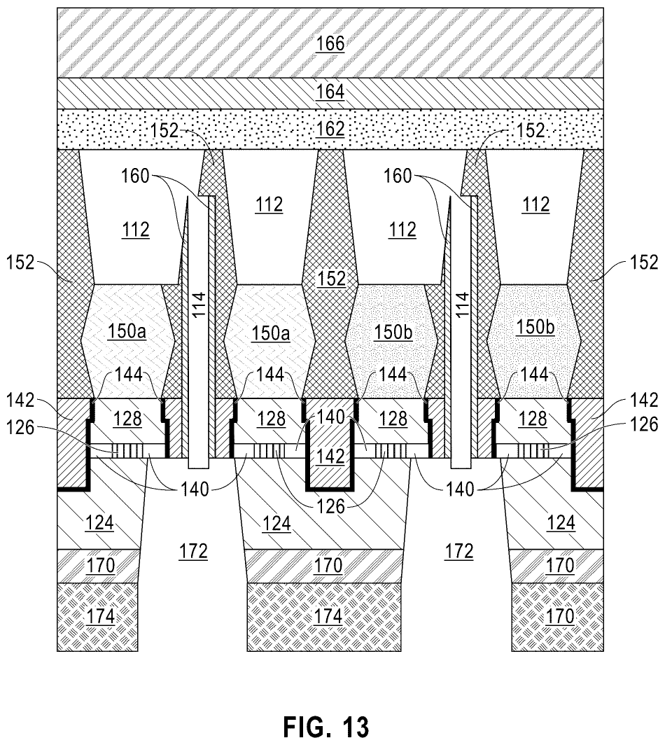

FIG. 13 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the formation of a backside interlayer dielectric (BILD) 170 and etching of backside power rail (RB) holes 172. A hard mask of organic planarization layer (OPL) 174 may facilitate the formation of the RB holes 172 in a lithographic process as described above. The etching of the RB holes 172 uses a selective etch process that etches the lower substrate 124 and the STI 142 more quickly than the dielectric etch stop inner spacers 140 or the backside vias 114. This selective etch process enables the backside vias 114 to be thoroughly exposed without damaging the portions of the lower substrate 124 and upper substrate 128 that are used to carry signals. That is, in semiconductor structures that do not include a dielectric etch stop inner spacer 140 (with no division of upper substrate 128 and lower substrate 124), the depth of the RB holes 172 will not be as accurate, and the bottom of the backside vias 114 may be unpredictably etched, causing potential defects. The dielectric etch stop inner spacers 140 prevent these defects by enabling accurate and known etch depths, and the conductivity of the remaining SiGe portion of the second etch stop layer 126 enables robust electrical communication between the upper substrate 128 and the lower substrate 124.

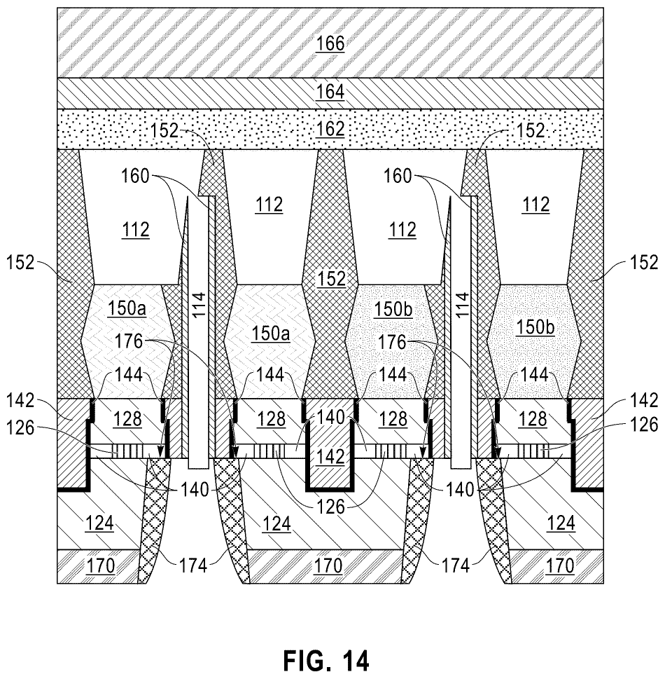

FIG. 14 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the formation of RB sidewalls 174 within the RB holes 172 to provide a barrier that protects the silicon of the lower substrate 124. The RB sidewalls 174 may be formed as a blanket layer of dielectric material (e.g., similar material to the BILD 170) followed by etchback/recessing to reveal the backside vias 114. The RB sidewalls 174 may include an edge 176 laterally overlapping the dielectric etch stop inner spacers 140 such that the dielectric etch stop inner spacers 140 are covered before the metallization of the backside power rail.

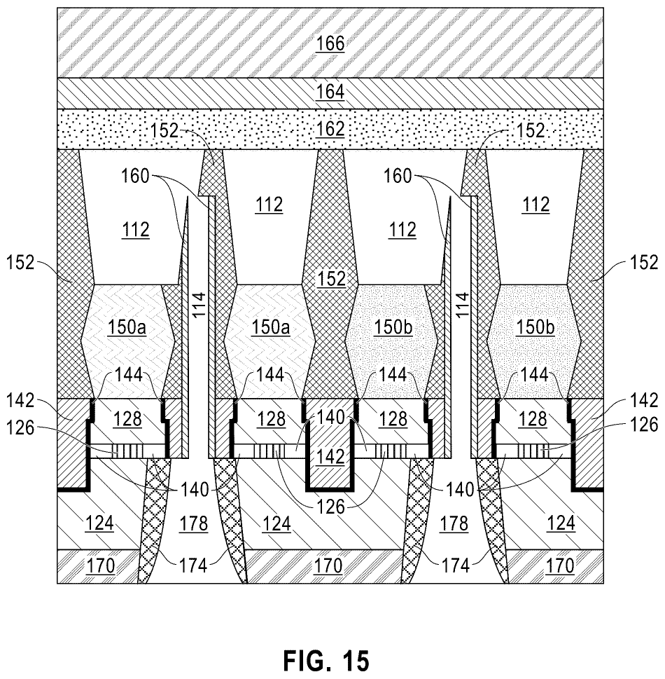

FIG. 15 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include the metallization of the RB holes 172 to form the backside power rail (RB) 178. The RB 178 forms with a robust connection to the backside vias 114 due to the exposure of the backside via 114 and to the minimal damage experienced by the backside vias 114 during any of the etch processes from the backside. The RB 178 is also thoroughly shielded from other conductive components such as the S/Ds 150, the upper substrate 128, the second etch stop layer 126, and the lower substrate 124 due to the accurate etching provided by the dielectric etch stop inner spacers 140 and the RB sidewalls 174 that partially overlap the dielectric etch stop inner spacers 140.

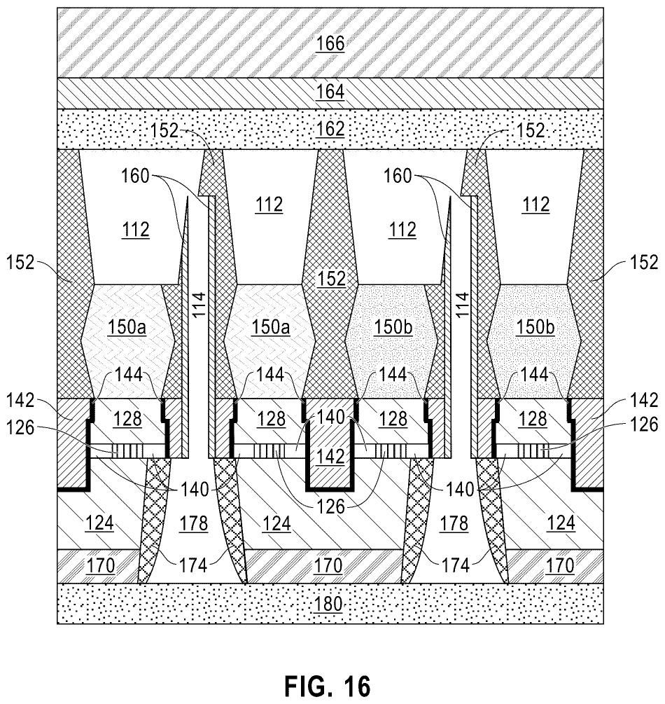

FIG. 16 depicts a cross-sectional side view of the semiconductor structure 100 (along line A-A′ in FIG. 1), with like reference numerals referring to like features at a fabrication stage of the processing method, in accordance with one embodiment of the present invention. The fabrication of the semiconductor structure 100 may include a backside power delivery network (BSPDN) 180 that provides power to the semiconductor structure 100 from the backside of the wafer. The BSPDN 180, like the BEOL 162, is not drawn to scale, and may include several metal layers of power interconnects or other power delivery structures. The BEOL 162 and/or the BSPDN 180 may include a substrate contact configured to supply a voltage potential to the lower substrate 124. The lower substrate 124 thus enables single direction signal flow between the first S/D 150a and the second S/D 150b.

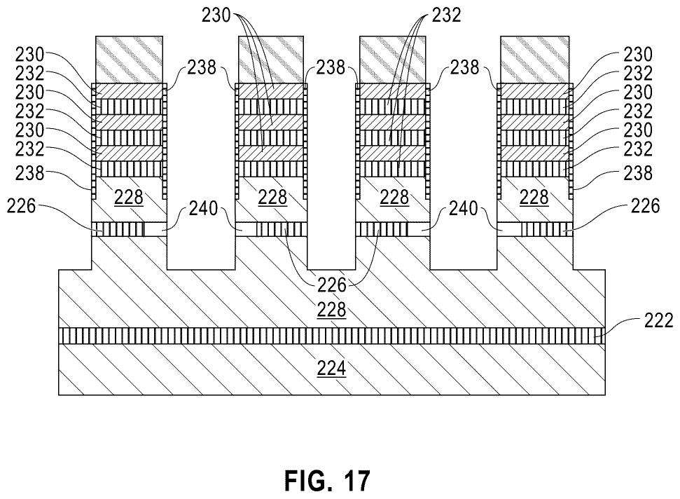

FIG. 17 depicts a cross-sectional side view of a semiconductor structure 200 at a fabrication stage of a processing method, in accordance with one embodiment of the present invention. The fabrication of the semiconductor structure 200 may include the same process steps illustrated in FIGS. 2 and 3 for the semiconductor structure 100 described above. In the embodiment shown in FIG. 17, however, a second etch stop layer 226 is indented/recessed only on one side, such that formation of dielectric etch stop inner spacers 240 only occurs on one side rather than both sides of the pillars (e.g., the pillars made up of a lower substrate 224, the second etch stop layer 222, an upper substrate 228, nanosheet channels 230, and dummy layers 232). A sidewall liner 238 protects the pillars from the etch process used to form the dielectric etch stop inner spacers 240. The single-side formation of the dielectric etch stop inner spacers 240 may be completed using a hard mask (e.g., OPL) to cover the areas where the second etch stop layer 226 will remain. This embodiment may be used when the etch stop inner spacer is only used at cell boundary regions to assist in forming backside power rail without shorting to the upper substrate 228.

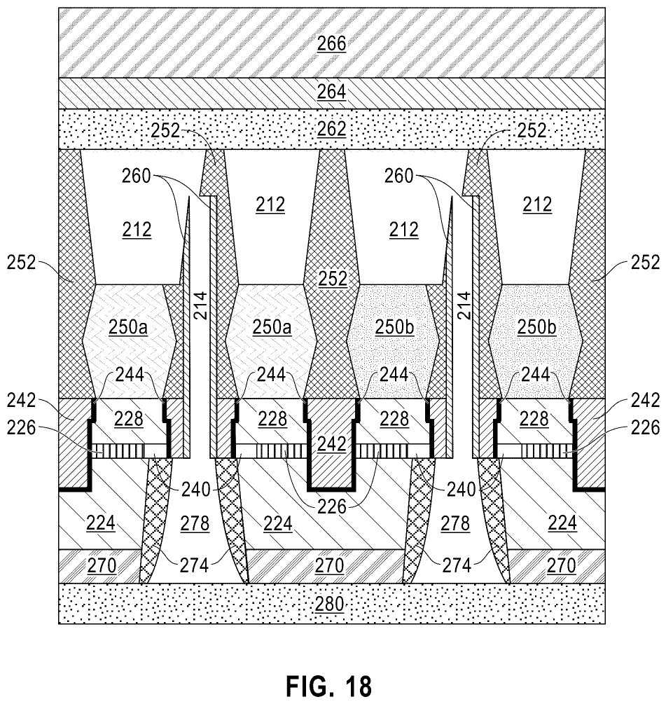

FIG. 18 depicts a cross-sectional side view of the semiconductor structure 200 of FIG. 17 at a fabrication stage of a processing method, in accordance with one embodiment of the present invention. The fabrication of the semiconductor structure 200 may include similar process steps to those described above with respect to the other semiconductor structure 100. Specifically, the steps to form shallow trench isolation (STI) 242, source/drains (S/Ds) 250a, b, ILD 252, backside vias 214, S/D contacts 212, a BEOL 262, a carrier wafer 266 bonded with a bonding oxide 264, then flipping the wafer to form RB sidewalls 274, a backside power rail 278, and a backside power delivery network 280 may all include similar deposition, patterning, and etching, processes to those described above. In particular, the formation of RB holes in the second semiconductor structure 200 utilizes the selective etch properties of the dielectric etch stop inner spacers 240 to accurately and precisely determine the depth of the RB holes. The RB sidewalls 274 will overlap the dielectric etch stop inner spacers 240 in the second semiconductor structure 200 as well. A lower substrate 224 (shielded from the BSPDN 280 by a backside interlayer dielectric (BILD) 270) may function as a passive device, enabling a single-direction signal to pass from a first S/D 250a to a second S/D 250b.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a deep via connecting a first source/drain (S/D) to a backside power rail (RB) below the first S/D;
a dielectric etch stop inner spacer below the first S/D; and
an RB sidewall surrounding the RB comprising an edge laterally overlapping the dielectric etch stop inner spacer.

2. The semiconductor structure of claim 1, wherein the dielectric etch stop inner spacer is located between an upper substrate and a lower substrate.

3. The semiconductor structure of claim 2, wherein the lower substrate is located under i) a second S/D, and ii) a shallow trench isolation (STI) between the first S/D and the second S/D.

4. The semiconductor structure of claim 3, further comprising a substrate contact configured to supply a voltage potential to the lower substrate, wherein the lower substrate enables single direction signal flow between the first S/D and the second S/D.

5. The semiconductor structure of claim 1, further comprising a silicon/germanium (SiGe) layer adjacent to the dielectric etch stop inner spacer.

6. The semiconductor structure of claim 5, further comprising a second dielectric etch stop adjacent to the SiGe layer.

7. The semiconductor structure of claim 1, wherein the dielectric etch stop inner spacer is attached to a shallow trench isolation (STI) that is located above the RB sidewall.

8. A method of fabricating a semiconductor structure, comprising:
etching an indentation in a silicon/germanium (SiGe) etch stop layer below a first source/drain;
filling the indentation with a dielectric etch stop inner spacer;
forming a deep via;
forming a backside power rail (RB) trench to expose the deep via, wherein the dielectric etch stop inner spacer stops the etch process forming the RB trench.

9. The method of claim 8, wherein forming the RB trench comprises etching a lower substrate without etching an upper substrate above the dielectric etch stop inner spacer.

10. The method of claim 8, further comprising forming a shallow trench isolation (STI) cavity to expose the SiGe etch stop layer.

11. The method of claim 10, wherein the deep via is formed in the STI cavity.

12. The method of claim 8, further comprising forming an RB sidewall in the RB trench, wherein the RB sidewall overlaps the dielectric etch stop inner spacer.

13. The method of claim 8, further comprising:
forming a back-end-of-line (BEOL) on a top side of the semiconductor structure;
flipping the semiconductor structure; and
forming a backside power delivery network (BSPDN) on a backside of the semiconductor structure.

14. A semiconductor structure, comprising:
a dielectric etch stop inner spacer below a first source/drain comprising a spacer thickness;
a silicon/germanium (SiGe) layer adjacent to the dielectric etch stop inner spacer, comprising a thickness that is the same as the spacer thickness; and
an RB sidewall comprising an edge laterally overlapping the dielectric etch stop inner spacer.

15. The semiconductor structure of claim 14, wherein the dielectric etch stop inner spacer is located between an upper substrate and a lower substrate.

16. The semiconductor structure of claim 15, wherein the lower substrate is located under i) a second S/D, and ii) a shallow trench isolation (STI) between the first S/D and the second S/D.

17. The semiconductor structure of claim 16, further comprising a substrate contact configured to supply a voltage potential to the lower substrate, wherein the lower substrate enables single direction signal flow between the first S/D and the second S/D.

18. The semiconductor structure of claim 14, further comprising a second dielectric etch stop adjacent to the SiGe layer.

19. The semiconductor structure of claim 14, wherein the dielectric etch stop inner spacer is attached to a shallow trench isolation (STI) that is located above the RB sidewall.

20. The semiconductor structure of claim 14, wherein the dielectric etch stop inner spacer is located between an upper substrate and a lower substrate.
